(19) United States
(12) Patent Application Publication
(10) Pub. No.: US 2022/0121252 A1
(43) Pub. Date: Apr. 21, 2022

(54) METAL BACK PLATE, DISPLAY APPARATUS, AND PRE-COATING METHOD OF METAL BACK PLATE

(71) Applicant: Shenzhen TCL Digital Technology Ltd., Shenzhen (CN)

(72) Inventors: Liqiang LIU, Shenzhen (CN); Bing LI, Shenzhen (CN); Zuo CHAI, Shenzhen (CN)

(21) Appl. No.: 17/565,522

(22) Filed: Dec. 30, 2021

Related U.S. Application Data
(63) Continuation of application No. PCT/CN2020/099206, filed on Jun. 30, 2020.

(30) Foreign Application Priority Data
Jul. 2, 2019 (CN) 201910589420.0

(51) Int. Cl. G06F 1/18; H05K 7/14

(52) U.S. Cl. CPC G06F 1/189; H05K 7/1438; G06F 1/181

(57) ABSTRACT

A metal back plate, a display apparatus, and a pre-coating method for a metal back plate are provided. The metal back plate is a pre-coated steel back plate (1), and comprises a conductive region (2) and a non-conductive region (3). A front surface pre-coated coating is provided on the non-conductive region (3). By reserving the conductive region (2) in the front surface pre-coated coating of the pre-coated steel back plate (1), the mounting region of a core circuit board on the pre-coated steel back plate (1) is conductive, thereby reducing the stamping and riveting processes and a threaded stud material, and reducing the production costs.

### CROSS REFERENCE TO RELATED APPLICATION

This application is a continuation application of an International Application No. PCT/CN2020/099206, filed on Jun. 30, 2020, which claims priority to Chinese Application No. 201910589420.0, filed on Jul. 2, 2019. The entire disclosures of the above applications are incorporated herein by reference.

### FIELD OF THE DISCLOSURE

The present disclosure relates to a back plate, and more particularly, to a metal back plate, a display device, a pre-coating method of the metal back plate.

### BACKGROUND

With the advancement of technology and the improvement of living standards, the shape and size of a television (TV) updates constantly. Nowadays, there is a tendency for a thin and large sized TV set. Based on the structural strength of the TV, the back plate material of the TV has been converted from plastic to metal.

The material of a metal back plate in the related art is formed by spraying paint after the metal back plate is punched with electric galvanized steel sheet. However, the process of spraying paint brings greater pollution to the environment. The paint-spraying process not only harms the environment and the health of the work workers but also spends more money on dealing with the emissions.

A steel sheet using a pre-coating method before molding is called a pre-coating steel sheet (PCM) back plate. The research on and application to the PCM back plate can solve the problem about spray as mentioned above. An area where the TV movement circuit board is arranged needs to conduct electricity, but the pre-coating layer of the PCM back plate is made of polyester organic material, which is a kind of non-conductive material.

The method of solving the problem of conductivity of the area where the TV movement circuit board is arranged is to add a metal conductive stud in the related art. However, the process and material cost increases due to the addition of the metal conductive stud in the related art. Therefore, it is necessary to find out an effective and low-cost solution.

### SUMMARY

An object of the present disclosure is to propose a metal back plate, a display device, a pre-coating method of the metal back plate to solve the problem of great expense of a conductive structure of a movement circuit board on a pre-coating metal sheet (PCM) back plate of the related art.

According to a first aspect of the present disclosure, a metal back plate includes the metal back plate is a pre-coating metal (PCM) back plate; the PCM back plate comprising a conductive area and a non-conductive area. A frontal pre-coating layer is disposed on the non-conductive area.

Optionally, wherein a zinc layer in the conductive area; the thickness of the zinc layer is three micrometers (μm) or more than three μm.

Optionally, the metal back plate comprises a metal substrate. The frontal pre-coating layer comprises a frontal passivation layer, a bottom coating layer, and a surface coating layer. The frontal passivation layer is disposed on a surface of the metal substrate. The bottom coating layer is pre-coating on the frontal passivation layer.

Optionally, the bottom coating layer is made of epoxy resin, polyester, or polyurethane; the surface coating layer is made of ordinary polyester, polymer polyester, modified polyester, scratch polyester, or polyurethane, or a combination of one or more of these materials.

Optionally, the sum of the thickness of the bottom coating layer and the thickness of the surface coating layer ranges from 10 μm to 30 μm.

Optionally, the metal back plate comprises a metal substrate; the frontal pre-coating layer comprises a frontal passivation layer and a surface coating layer. The frontal passivation layer is disposed on a surface of the metal substrate; the surface coating layer is pre-coating on the frontal passivation layer.

Optionally, the surface coating layer is made of ordinary polyester, polymer polyester, modified polyester, scratch polyester, or polyurethane, or a combination of one or more of these materials.

Optionally, the thickness of the surface coating layer ranges from 5 μm to 15 μm.

Optionally, the metal back plate comprises a metal substrate; a rear pre-coating layer is disposed on a surface of the metal substrate and a surface of a frontal pre-coating layer. The metal substrate is arranged opposite to the frontal pre-coating layer. The rear pre-coating layer comprises a rear passivation layer and a rear painting layer. The rear passivation layer is disposed on the surface of the metal substrate. The rear painting layer is pre-coating on the rear passivation layer.

Optionally, the metal back plate comprises a metal substrate. A rear pre-coating layer is disposed on a surface of the metal substrate and a surface of a frontal pre-coating layer. The metal substrate is arranged opposite to the frontal pre-coating layer. The rear pre-coating coating layer comprises a rear passivation layer on a surface of the metal substrate. A bottom coating layer, a surface coating layer, and a rear painting layer are sequentially disposed on the rear passivation layer.

Optionally, a protective film is disposed on the rear painting layer.

Optionally, the rear painting layer is modified epoxy rear paint.

Optionally, the metal back plate is a hot dipped zinc sheet or an electric galvanized steel sheet.

According to a second aspect of the present disclosure, a display device includes a metal back plate and a movement circuit board. The movement circuit board is arranged in the conductive area.

According to a third aspect of the present disclosure, a pre-coating method of a metal back plate includes: pre-coating a frontal coating layer of a pre-coating metal back plate. The pre-coating a frontal coating layer of a pre-coating metal back plate comprises: setting an area for a conductive area based on a parameter of a pre-coating process and a size of the conductive area of a metal back plate; and coating the frontal coating layer on the metal back plate to avoid coating on the hollow area.

Optionally, the pre-coating a frontal coating layer of a pre-coating metal back plate comprises: sticking a piece of adhesive sticker on an area of the metal back plate, wherein the area corresponding to a conductive area of the metal back plate, and a size of the piece of adhesive sticker fits a size of the conductive area; rolling a frontal pre-coating layer on the metal back plate; and removing the piece of adhesive sticker after the rolling is finished.

Optionally, the method further comprises: coating a back coating layer on a back side of the metal back plate by curtain flow, spray, two-roll reverse coating, or three-roll reverse coating.

The present disclosure provides beneficial effects as follows.

A conductive area is reserved for a pre-coating layer on a PCM back plate to realize conductivity of the installation area on a movement circuit board on a PCM back plate in the present disclosure to replace the stamping riveting process and material for making studs in the related art and reduce production costs.

### BRIEF DESCRIPTION OF THE DRAWINGS

These and other features of the present disclosure will become apparent from the following description of some embodiments, given as a non-restrictive example with reference to the attached drawings where:

FIG. 1 is a schematic diagram of an overall structure of a metal back plate in the present embodiment.

FIG. 2 is a schematic diagram of a surface coating as a double-layer coating in the present embodiment.

FIG. 3 is a schematic diagram of a surface coating as a single-layer coating in the present embodiment.

### DETAILED DESCRIPTION OF THE EMBODIMENTS

The invention is described below in detail with reference to the accompanying drawings, wherein like reference numerals are used to identify like elements illustrated in one or more of the figures thereof, and in which exemplary embodiments of the invention are shown. This invention may, however, be embodied in many different forms and should not be construed as limited to the particular embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It is understood that terminologies, such as “center,” “longitudinal,” “horizontal,” “length,” “width,” “thickness,” “upper,” “lower,” “before,” “after,” “left,” “right,” “vertical,” “horizontal,” “top,” “bottom,” “inner,” “outer,” “clockwise,” and “counterclockwise,” are locations and positions regarding the figures. These terms merely facilitate and simplify descriptions of the embodiments instead of indicating or implying the device or components to be arranged on specified locations, to have specific positional structures and operations. These terms shall not be construed in an ideal or excessively formal meaning unless it is clearly defined in the present specification.

In addition, the term “first”, “second” are for illustrative purposes only and are not to be construed as indicating or imposing a relative importance or implicitly indicating the number of technical features indicated. Thus, a feature that limited by “first”, “second” may expressly or implicitly include at least one of the features. In the description of the present disclosure, the meaning of “plural” is two or more, unless otherwise specifically defined.

All of the terminologies containing one or more technical or scientific terminologies have the same meanings that persons skilled in the art understand ordinarily unless they are not defined otherwise. For example, “arrange,” “couple,” and “connect,” should be understood generally in the embodiments of the present disclosure. For example, “firmly connect,” “detachably connect,” and “integrally connect” are all possible. It is also possible that “mechanically connect,” “electrically connect,” and “mutually communicate” are used. It is also possible that “directly couple,” “indirectly couple via a medium,” and “two components mutually interact” are used.

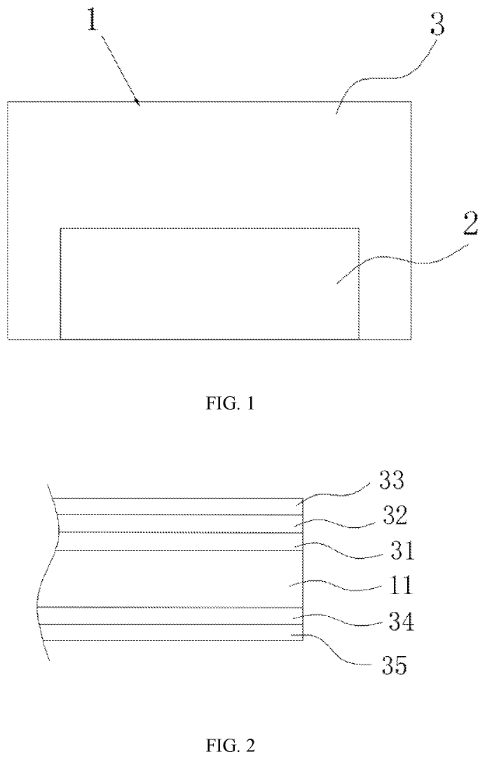

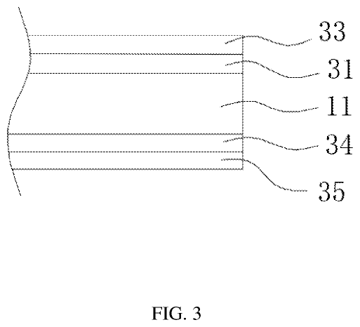

A metal back plate as illustrated in FIG. 1 to FIG. 3 is proposed by a preferred embodiment of the present disclosure. The metal back plate is a pre-coating metal (PCM) back plate 1. The PCM back plate 1 includes a conductive area 2 and a non-conductive area 3. The front of the PCM back plate 1 includes the conductive area 2 equipped with a movement circuit board which matches the conductive area 2 and the non-conductive area 3 which is arranged outside the conductive area 2. A frontal pre-coating layer is disposed on the non-conductive area 3, and a rear pre-coating layer is disposed on the back of the PCM back plate 1.

The PCM back plate 1 not only meets the requirements of household appliances and service life but also has excellent molding process. So the PCM back plate 1 can meet the requirements of high speed, precision processing equipment and can be produced in batches.

The present disclosure adopts the metal back plate of the PCM back plate that is configured to produce a television (TV). A partial pre-coating coating layer is arranged on the PCM material production and some space is reserved for the conductive area. Electricity is conducted to an area where the movement circuit board of PCM back plate 1 is arranged. Moreover, the designer of the present disclosure can design a conductive area of the PCM back plate 1. Compared with the electricity conduction of riveting stud in the related art, the stamping riveting process and material for making studs in the related art is omitted in the present disclosure, thereby realizing the purpose of lowering the design costs for electricity conduction of the area for the arrangement of the movement circuit board of PCM back plate 1.

The PCM back plate 1 is a hot dipped zinc sheet or an electric galvanized steel sheet. The metal substrate 11 employed by the PCM back plate 1 is a cold-rolled hot dip galvanized steel sheet (SGCC) or a cold rolled steel sheet (SECC).

A zinc layer adapted to the shape of the movement circuit board is arranged in the conductive area 2. The thickness of the zinc layer is three micrometers (μm) or more than three μm.

The thickness of the zinc layer of the conductive area 2 on the frontal movement circuit board of the PCM back plate 1 is greater or equal to three μm to meet the requirement of the movement area on the back plate of a TV for conductivity. The frontal conductive area 2 of the PCM back plate 1 may be shaped as a rectangle, a circular arc, a triangle, or a trapezoid, or a combination of one or more these shapes. Further, the frontal conductive area 2 may be shaped as an irregular circle. The frontal conductive area 2 is arranged based on conductivity.

If the structure of the frontal pre-coating layer is double-layer coating, the PCM back plate 1 includes a metal substrate 11. The frontal pre-coating layer includes a frontal passivation layer 31, a bottom coating layer 32, and a surface coating layer 33. The frontal passivation layer 31 is disposed on the surface of the metal substrate 11. The bottom coating layer 32 is pre-coating on the frontal passivation layer 31.

Passivation refers to the surface of metal converted into a hard-to-oxidate state to delay metal corrosion speed. Passivation is due to metal and oxidized substances. When passivation acts, a very thin and dense passivation film is formed on the surface of metal, and the passivation film firmly absorbs and well covers the surface of metal. The passivation film is present in an independent phase, usually a compound of the oxide metal. The passivation film isolates metal from the corrosion medium completely and prevents metal from touching the corrosion medium.

Compared with the physical enclosure of the related art, features like no increase in the thickness of workpieces and no change in color are demonstrated after the passivation treatment. Accordingly, the product precision is enhanced and the method of operation is easier.

When the frontal passivation layer is produced in the present disclosure, the metal substrate of the PCM back plate 1 is arranged in a passivation solution for 20 minutes and the temperature of the passivation solution keeps 25 to 35 degrees Celsius (° C.). Afterwards, the metal substrate is removed from the passivation solution and baked in an environment of 200° C. for 10 minutes.

When the metal substrate finishes being baked, the temperature of the metal substrate is left to be cooled to 30° C. at a speed of two degrees Celsius per minute (° C./min). When the temperature of the metal substrate is 30° C., the metal substrate was rinsed with water at 10° C. Finally, the metal substrate is blown to dry off with gas.

The bottom coating layer 32 is made of epoxy resin, polyester, or polyurethane. The surface coating layer 33 is made of ordinary polyester, polymer polyester, modified polyester, scratch polyester, or polyurethane, or a combination of one or more of these materials. The sum of the thickness of the bottom coating layer 32 and the thickness of the surface coating layer 33 ranges from 10 μm to 30 μm.

If the structure of the frontal pre-coating layer is single-layer coating, the PCM back plate 1 includes a metal substrate 11. The frontal pre-coating layer includes a frontal passivation layer 31 and a surface coating layer 33. The frontal passivation layer 31 is disposed on the surface of the metal substrate 11. The surface coating layer 33 is disposed on the frontal passivation layer 31.

The surface coating layer 33 is made of ordinary polyester, polymer polyester, modified polyester, scratch polyester, or polyurethane, or a combination of one or more of these materials. The thickness of the surface coating layer 33 ranges from 5 μm to 15 μm.

In the present embodiment, the non-conductive area 3 is completely arranged on the front of the PCM back plate 1 except the conductive area 2. Specifically, the non-conductive area 3 is arranged on the frontal pre-coating layer on the front of the PCM back plate 1. The frontal pre-coating layer may be a double-coating layer. In other words, the frontal pre-coating layer includes a metal substrate that includes the frontal passivation layer 31, the bottom coating layer 32, and the surface coating layer 33. The frontal pre-coating layer may be a single-coating layer. In other words, the frontal pre-coating layer includes a metal substrate that includes the frontal passivation layer 31 and the surface coating layer 33.

If the structure of the frontal pre-coating layer on the front of the PCM back plate 1 is double-layer coating, the bottom coating layer 32 may be epoxy resin, polyester, or polyurethane. The surface coating layer 33 may be ordinary polyester, polymer polyester, polyurethane, modified polyester, or scratch polyester, or a combination of one or more of these materials. The thickness of the double-layer coating structure ranges from 10 μm to 30 μm totally.

If the structure of the frontal pre-coating layer on the front of the PCM back plate 1 is single-layer coating, the surface coating layer 33 may be ordinary polyester, polymer polyester, polyurethane, modified polyester, or scratch polyester, or a combination of one or more of these materials. The thickness of the single-layer coating structure ranges from 5 μm to 15 μm totally.

In another preferred embodiment of the present disclosure, a metal back plate includes a metal substrate 11. A rear pre-coating layer is disposed on a surface of a metal substrate 11 and a surface of a frontal pre-coating layer. The metal substrate 11 is arranged opposite to the frontal pre-coating layer. The rear pre-coating layer includes a rear passivation layer 34 and a rear painting layer 35. The rear passivation layer 34 is disposed on the surface of the metal substrate 11. The rear painting layer 35 is pre-coating on the rear passivation layer 34. Specifically, the rear painting layer 35 is modified epoxy rear paint.

In another preferred embodiment of the present disclosure, a rear pre-coating coating layer further includes a rear passivation layer 34 on a surface of a metal substrate 11 of a pre-coating steel sheet (PCM) back plate 1. A bottom coating layer 32, a surface coating layer 33, and a rear painting layer 35 are coated on the rear passivation layer 34 at once. A protective film is disposed on the rear painting layer 35.

In the present disclosure, the surface coating layer 33 of the PCM back plate has excellent mechanical properties such as scratch resistance, dielectric, and moldable. Besides, the surface coating layer 33 of the PCM back plate has no heavy metals, non-ethylene, no ether solvents, and no hazardous substances which regulations do not allow. There is no volatilization of organic solvents in the production process of the PCM back plate; instead, the production process of the PCM back plate is green and environmentally friendly and very efficient. The PCM back plate of the present disclosure can be applied to not only TVs but also a variety of home appliances.

The present disclosure further includes a display device. The display device includes a metal back plate and a movement circuit board as introduced above. The movement circuit board is arranged in the conductive area.

The present disclosure further proposes a pre-coating method of the metal back plate. The pre-coating method includes: coating a frontal coating layer on a front side of a metal back plate, and coating a back coating layer on a back side of the metal back plate by curtain flow, spray, two-roll reverse coating, or three-roll reverse coating. In one embodiment of the present disclosure, the coating the frontal coating layer on the front side of a metal back plate includes: setting an area for a conductive area based on a parameter of a pre-coating process and a size of the conductive area of a metal back plate, and coating the frontal coating layer on the metal back plate to avoid coating on the hollow area. In another preferred embodiment of the present disclosure, the coating the frontal coating layer on the front side of a metal back plate includes: sticking a piece of adhesive sticker on an area of the metal back plate, where the area corresponding to a conductive area of the metal back plate, and a size of the piece of adhesive sticker fits a size of the conductive area; rolling a frontal pre-coating layer on the metal back plate; and removing the piece of adhesive sticker after the rolling is finished.

In the present embodiment, the method of designing local pre-coating roll-coating to prepaint the back plate partially is to perform clearance roll-coating for the conductive area in the pre-coating process by pre-coating the hollow area of the roll combined with the arrangement of the hollow area of the roll based on the parameter of the pre-coating process according to the size of the conductive area. Or, the method of designing local pre-coating roll-coating to prepaint the back plate partially is to stick a piece of thin adhesive paper of which size is consistent with the size of the conductive area onto a galvanized plate according to the size of the metal back plate and the size of the conductive area, to roll the pre-coating layer, and to remove the piece of thin adhesive paper after the pre-coating is finished.

Further, the metal back plate is pre-coating with a roll coating device in the present embodiment. Firstly, the metal substrate is trimmed Secondly, the metal substrate is given the corona treatment with a corona machine. Thirdly, the electrostatic dust is removed with an electrostatic dust collecting machine. Fourthly, the metal substrate is roll-coated with a roll-coating machine unit. Fifthly, the metal substrate, which has been roll-coated with the trimming machine, is cut to be metal material with a predetermined size. Finally, a suitable metal back plate is obtained by stamping molding.

The pre-coating method of the rear pre-coating layer includes curtain flow, spray, two-roll reverse coating, or three-roll reverse coating.

Preferably, the two-roll reverse coating method or the three-roll reverse coating method is that the rear pre-coating layer is pre-coating in the present embodiment.

If the two-roll reverse coating method is adopted, a hard chrome-plated roll or a net roller belt is taken as a belt roller and a rubber roller is taken as a coating roller, which is suitable for plain coatings with low viscosity or fair viscosity. Especially, the speed of coating the rubber roller is 1.1 to 1.8 times the linear speed of coating the rubber roller. The speed of the net roller belt is 0.2 to 0.6 times the linear speed. If the speed of meshing the two rolls higher, the stress of a paint liquid there is too great, causing the coating film to be unstable and uneven.

If the three-roll reverse coating method is adopted, a hard chrome-plated roll or a net roller belt is taken as an ink distributing roller or a belt roller and a rubber roller is taken as a coating roller, which is suitable for coatings with metal pigments and coatings with greater particles. The speed of the ink distributing roller, the belt roller, and the coating roller is 0.2 to 0.5 times, 1.0 to 1.4 times, or 1.3 to 2.0 times the linear speed.

Compared with two-roll reverse coating, three-roll reverse coating is suitable for coatings with which the viscosity is fair or good, and the thickness of the film of the three-roll reverse coating can be regulated. So the advection of the three-roll reverse coating is better.

In sum, the conductive area on the frontal pre-coating layer of the PCM back plate 1 is reserved to make the area where the movement circuit board on the PCM back plate 1 is arranged is electrically conducted. Compared with the electricity conduction of the riveting stud in the related art, the stamping riveting process and material for making the stud in the related art is omitted in the present disclosure. Thereby, the conductive area on the PCM back plate 1 is partially reserved to be pre-coating at a lower cost, and restrictions upon the design of electrical conductivity of the PCM back plate 1 are lifted as well.

The above embodiment of this invention offers a display screen, a display device, and a method for manufacturing the display screen in the herein application specific exception to the principle of the invention and embodiments have discussed, more embodiment of is only used to help to understand the description of the method of the present invention and its core idea; at the same time, for the general technical personnel in this field, according to the idea of the invention, the specific embodiment and application range at will a change, in sum, the contents of this specification should not be understood to limit the present invention.

What is claimed is:

1. A metal back plate, being a pre-coating metal (PCM) back plate, the PCM back plate comprising:
a conductive area; and
a non-conductive area, comprising a frontal pre-coating layer disposed on the non-conductive area.

2. The metal back plate according to claim 1, wherein a zinc layer is disposed on the conductive area; a thickness of the zinc layer is three micrometers (μm) or more than three μm.

3. The metal back plate according to claim 1, wherein the metal back plate comprises a metal substrate; the frontal pre-coating layer comprises a frontal passivation layer, a bottom coating layer, and a surface coating layer; the frontal passivation layer is disposed on a surface of the metal substrate; the bottom coating layer is pre-coating on the frontal passivation layer.

4. The metal back plate according to claim 3, wherein the bottom coating layer is made of epoxy resin, polyester, or polyurethane; the surface coating layer is made of ordinary polyester, polymer polyester, modified polyester, scratch polyester, or polyurethane, or a combination of one or more of these materials.

5. The metal back plate according to claim 4, wherein a sum of the thickness of the bottom coating layer and the thickness of the surface coating layer ranges from 10 micrometers (μm) to 30 μm.

6. The metal back plate according to claim 1, wherein the metal back plate comprises a metal substrate; the frontal pre-coating layer comprises a frontal passivation layer and a surface coating layer; the frontal passivation layer is disposed on a surface of the metal substrate; the surface coating layer is pre-coating on the frontal passivation layer.

7. The metal back plate according to claim 6, wherein the surface coating layer is made of ordinary polyester, polymer polyester, modified polyester, scratch polyester, or polyurethane, or a combination of one or more of these materials.

8. The metal back plate according to claim 7, wherein the thickness of the surface coating layer ranges from 5 micrometers (μm) to 15 μm.

9. The metal back plate according to claim 1, wherein the metal back plate comprises a metal substrate; a rear pre-coating layer is disposed on a surface of the metal substrate and a surface of a frontal pre-coating layer; the metal substrate is arranged opposite to the frontal pre-coating layer; the rear pre-coating layer comprises a rear passivation layer and a rear painting layer; the rear passivation layer is disposed on the surface of the metal substrate; the rear painting layer is pre-coating on the rear passivation layer.

10. The metal back plate according to claim 1, wherein the metal back plate comprises a metal substrate; a rear pre-coating layer is disposed on a surface of the metal substrate and a surface of a frontal pre-coating layer; the metal substrate is arranged opposite to the frontal pre-coating layer; the rear pre-coating coating layer comprises a rear passivation layer on a surface of the metal substrate; a bottom coating layer, a surface coating layer, and a rear painting layer are sequentially disposed on the rear passivation layer.

11. The metal back plate according to claim 10, wherein a protective film is disposed on the rear painting layer.

12. The metal back plate according to claim 9, wherein the rear painting layer is modified epoxy rear paint.

13. The metal back plate according to claim 1, wherein the metal back plate is a hot dipped zinc sheet or an electric galvanized steel sheet.

14. A display device, comprising:
a metal back plate; and
a movement circuit board, arranged in the conductive area.

15. A method of pre-coating a metal back plate, comprising:
coating a frontal coating layer on a front side of a metal back plate, comprising:
setting an area for a conductive area based on a parameter of a pre-coating process and a size of the conductive area of a metal back plate; and
coating the frontal coating layer on the metal back plate to avoid coating on the hollow area; or
sticking a piece of adhesive sticker on an area of the metal back plate, wherein the area corresponding to a conductive area of the metal back plate, and a size of the piece of adhesive sticker fits a size of the conductive area;
rolling a frontal pre-coating layer on the metal back plate; and
removing the piece of adhesive sticker after the rolling is finished.

16. The method according to claim 15, further comprising:
coating a back coating layer on a back side of the metal back plate by curtain flow, spray, two-roll reverse coating, or three-roll reverse coating.
